(19) United States
(12) Patent Application Publication
(10) Pub. No.: US 2024/0407235 A1
(43) Pub. Date: Dec. 5, 2024

(54) LIGHT EMITTING MODULE AND DISPLAY DEVICE

(71) Applicant: HKC CORPORATION LIMITED, Shenzhen (CN)

(72) Inventors: Mei ZHANG, Shenzhen (CN); Lidan YE, Shenzhen (CN)

(21) Appl. No.: 18/642,037

(22) Filed: Apr. 22, 2024

(30) Foreign Application Priority Data
Jun. 2, 2023 (CN) 202310647866.0

(51) Int. Cl. H10K 59/80; H05K 5/02

(52) U.S. Cl. CPC H10K 59/873; H05K 5/0217; H10K 59/878; H10K 59/8794

(57) ABSTRACT

A light-emitting module and a display device are disclosed. The light-emitting module includes a substrate, a light-emitting element, and a protective sealant. The protective sealant has a thermal expansion rate that is greater than a thermal expansion rate of the substrate. There is defined a plurality of grooves in a side of the substrate facing the protective sealant. Each groove is disposed between adjacent light-emitting elements.

### CROSS-REFERENCE TO RELATED APPLICATIONS

This application claims the priority and benefit of Chinese patent application number 202310647866.0, titled “Light Emitting Module and Display Device” and filed Jun. 2, 2023 with China National Intellectual Property Administration, the entire contents of which are incorporated herein by reference.

### TECHNICAL FIELD

This application relates to the field of display technology, and more particularly relates to a light-emitting module and a display device.

### BACKGROUND

The description provided in this section is intended for the mere purpose of providing background information related to the present application but doesn't necessarily constitute prior art.

The light source of a display device may adopt two forms: backlit and self-luminous. Examples of backlit displays include LCD (Liquid Crystal Display). Examples of self-luminous displays include OLED (Organic Light-Emitting Diode) and Micro LED (Micro Light Emitting Diode Display).

However, regardless of whether it be backlight or self-illumination, when the light source is turned on, the temperature of the light source structure may rise rapidly, and the lights may go out, resulting in increased maintenance costs and even scrapping.

### SUMMARY

In view of the above, it is a purpose of this application to provide a light-emitting module and a display device to overcome the light-out phenomenon of the display device during long-term operation.

This application discloses a light-emitting module. The light-emitting module includes a substrate, an array of light-emitting elements arranged on the substrate, and a protective sealant covering the light-emitting elements. A thermal expansion rate of the protective sealant is greater than a thermal expansion rate of the substrate. A plurality of grooves are defined in the side of the substrate facing the protective sealant, and the grooves are arranged between adjacent light-emitting elements.

Optionally, the plurality of grooves are divided into a first groove group and a second groove group. A plurality of grooves in the first groove group are arranged along a first orientation. A plurality of grooves in the second groove group are arranged along a second orientation. The first orientation and the second orientation are respectively parallel to two vertical sides of the substrate. In the first groove group, both ends of each groove extend in the second orientation, and the two ends of the groove are flush with two opposite sides of the substrate respectively. In the second groove group, both ends of each groove extend in the first orientation, and the two ends of the groove are respectively flush with the other two opposite sides of the substrate.

Optionally, in the first groove group, the depth of each groove gradually decreases from the middle to both ends. In the second groove group, the depth of each groove gradually decreases from the middle to both ends.

Optionally, the light-emitting module also includes a backplate. The substrate is arranged on the backplate. The grooves in the first groove group meet with the grooves in the second groove group to form intersections. The substrate defines through holes corresponding to the intersections. The backplate includes a plurality of positioning posts on one side facing the substrate. The positioning posts are integrally formed with the backplate, and the positioning posts correspond to the through holes one by one. Each positioning post penetrates the respective through hole and contacts the protective sealant.

Optionally, the height of the end of each positioning post away from the backplate is higher than the height of the side of the substrate away from the backplate.

Optionally, the surface of the positioning post is coated with a reflective coating.

Optionally, the light-emitting module also includes a backplate. The substrate is arranged on the backplate. A plurality of channels are defined in the side of the substrate facing the backplate. The orthographic projection of each channel on the backplate overlaps the orthographic projection of the light-emitting elements on the backplate. A plurality of bosses are disposed on the side of the backplate facing the substrate, and the bosses are fitted with the channels in one-to-one correspondence.

Optionally, the inner wall of the groove is arc-shaped, and a reflective layer is disposed in the groove. The groove and the reflective layer jointly form a concave mirror structure.

Optionally, the light-emitting module also includes a backplate and an optical film. The substrate is arranged on the backplate. The optical film is disposed on the side of the protective sealant away from the substrate. A prism is disposed on a side of the optical film facing the substrate, and the orthographic projection of the prism on the backplate covers the orthographic projection of the groove on the backplate.

This application also discloses a display device. The display device includes a driving circuit and the light-emitting module as described above, where the driving circuit is used to drive the light-emitting module.

In a room temperature environment, the substrate and the protective sealant are in a zero-stress state, and the light-emitting element is not stressed. After the light-emitting elements are lit, the substrate and the protective sealant expand due to heat. Since the thermal expansion rate of the protective sealant is greater than the thermal expansion rate of the substrate, a slight displacement occurs between the substrate and the protective sealant, causing the light-emitting element to fail due to the squeeze of the protective sealant, resulting in a light-out phenomenon. Based on this, this application designs multiple grooves in the side of the substrate facing the protective sealant to mechanically compensate the substrate, so that the deformation of the substrate at the position of each of the grooves is relatively larger, and the overall deformation effect of the substrate increases, so that the expansion effect of the substrate matches the overall expansion degree of the protective sealant. Furthermore, the groove is disposed between adjacent light-emitting elements, which only increases the deformation amount of the portion of the substrate between the adjacent light-emitting elements, while the deformation amount of the portion of the substrate below each of the light-emitting elements is relatively small. Therefore, the relative displacement between the protective sealant and the substrate at the position of the light-emitting element is small, which reduces the squeeze on the light-emitting element and overcomes the light-out phenomenon.

### BRIEF DESCRIPTION OF DRAWINGS

The accompanying drawings are used to provide a further understanding of the embodiments according to this application, and constitute a part of the specification. They are used to illustrate the embodiments according to this application, and explain the principle of this application in conjunction with the text description. Apparently, the drawings in the following description merely represent some embodiments of the present disclosure, and for those having ordinary skill in the art, other drawings may also be obtained based on these drawings without investing creative efforts. A brief description of the accompanying drawings is provided as follows.

FIG. 1 is a schematic diagram of a display device provided by an embodiment according to this application.

FIG. 2 is a schematic cross-sectional view of a light-emitting module provided by an embodiment according to this application.

FIG. 3 is a schematic plan view of a light-emitting module provided by an embodiment according to this application.

FIG. 4 is a schematic cross-sectional view of a light plate assembly in an embodiment according to this application.

FIG. 5 is a schematic cross-sectional view of another light-emitting module in an embodiment according to this application.

FIG. 6 is an enlarged schematic diagram based on portion A shown in FIG. 2.

FIG. 7 is another enlarged schematic diagram based on portion A shown in FIG. 2.

FIG. 8 is a schematic cross-sectional view of another light-emitting module in an embodiment according to this application.

In the drawings: 10. Display device; 100. Light-emitting module; 110. Backplate; 111. Positioning post; 112. Boss; 120. Light plate assembly; 121. Substrate; 122. Light-emitting element; 123. Protective sealant; 124. Groove; 124a. First groove group; 124b. Second groove group; 125. Through hole; 126. trough; 127. Reflective layer; 130. Optical film; 131. Prism; 200. Driving circuit; X. First orientation; Y. Second orientation.

### DETAILED DESCRIPTION OF EMBODIMENTS

It should be understood that the terms used herein, the specific structures and function details disclosed herein are intended for the mere purposes of describing specific embodiments and are representative. However, this application may be implemented in many alternative forms and should not be construed as being limited to the embodiments set forth herein.

Furthermore, as used herein, terms “mounted on”, “connected to”, “coupled to”, “connected with”, and “coupled with” should be understood in a broad sense unless otherwise specified and defined. For example, they may indicate a fixed connection, a detachable connection, or an integral connection. They may denote a mechanical connection, or an electrical connection. They may denote a direct connection, a connection through an intermediate, or an internal connection between two elements. For those of ordinary skill in the art, the specific meanings of the above terms as used in this application can be understood depending on specific contexts.

As shown in FIG. 1, an embodiment according to this application provides a display device. The display device 10 includes a driving circuit 200 and a light emitting module 100. The driving circuit 200 is used to drive the light emitting module 100. When the display device 10 adopts backlight display, the display device 10 is a liquid crystal display device, and the light-emitting module 100 is a backlight module. The light-emitting module 100 adopts a direct-lit design and may be a Mini LED light-emitting module. When the display device 10 adopts self-luminous display, the display device 10 is an OLED display device or a Micro LED display device, and the light-emitting module 100 is the light emitting part of the display panel, specifically including a light-emitting element (light-emitting material or LED lamp), a substrate carrying the light-emitting element, and a protective sealant covering the light-emitting element.

For brevity of explanation, the following description assumes that the display device 10 is a liquid crystal display device. In this case, the light-emitting module 100 is a backlight module, and the light-emitting element is a light-emitting chip or a lamp bead.

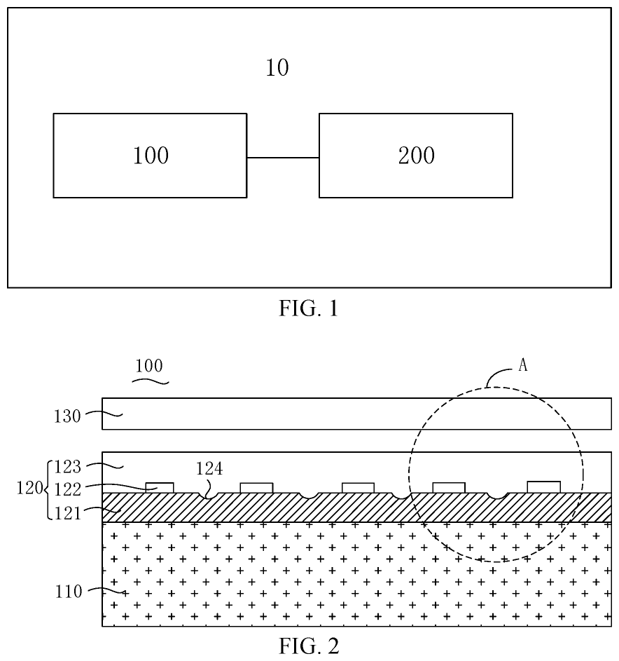

As shown in FIG. 2, the light-emitting module 100 includes a backplate 110, a light plate assembly 120 disposed on the backplate 110, and an optical film 130 disposed on the light plate assembly 120. The light plate assembly 120 includes a substrate 121, light-emitting elements 122 arranged in an array on the substrate 121, and a protective sealant 123 covering the light-emitting elements 122. The substrate 121 may be made of a plastic or resin material, such as glass fiber reinforced thermosetting resin, polyimide or polytetrafluoroethylene, etc. Furthermore, the thermal expansion coefficient of the protective sealant 123 is greater than the thermal expansion coefficient of the substrate 121.

A plurality of grooves 124 are disposed in the side of the substrate 121 facing the protective sealant 123. Each groove 124 is disposed between two adjacent light-emitting elements 122. It may be disposed between adjacent light-emitting elements 122 in a partial area on the substrate 121, or may be disposed between adjacent light-emitting elements 122 in the entire area on the substrate 121.

In a room temperature environment, the substrate 121 and the protective sealant 123 are in a zero-stress state, and the light-emitting element 122 is not stressed. After the light-emitting elements 122 are lit, the light plate expands due to heat. Since the thermal expansion rate of the protective sealant 123 is greater than the thermal expansion rate of the substrate 121 such that the expansion degree of the protective sealant 123 is greater than the expansion degree of the substrate 121, a slight displacement may occur between the substrate 121 and the protective sealant 123, which may cause the light-emitting element 122 to fail due to the lateral squeeze of the protective sealant 123, resulting in a light-out phenomenon. For example, the squeeze of the protective sealant 123 may cause the solder between the light-emitting element 122 and the substrate 121 to crack, causing the electrical connection between the light-emitting element 122 and the pad to fail, causing some of the light-emitting elements 122 (lamp beads) to go out.

Based on this, this application designs multiple grooves 124 in the side of the substrate 121 facing the protective sealant 123 to mechanically compensate the substrate 121, so that the deformation of the substrate 121 at the position of each of the grooves 124 is relatively larger, and the overall deformation amount of the substrate 121 increases, so that the overall expansion degree of the substrate 121 matches the overall expansion degree of the protective sealant 123. Furthermore, the groove 124 is disposed between adjacent light-emitting elements 122, which only increases the deformation amount of the portion of the substrate 121 between the adjacent light-emitting elements 122, while the deformation amount of the portion of the substrate 121 below each of the light-emitting elements 122 is relatively small. Therefore, the relative displacement between the protective sealant 123 and the substrate 121 at the position of the light-emitting element 122 is small, which reduces the squeeze on the light-emitting element 122 and overcomes the light-out phenomenon.

Furthermore, as an implementation, the protective sealant 123 is also filled in the grooves 124. During the manufacturing process of the light plate assembly 120, the grooves 124 are first made in the substrate 121. When the protective sealant 123 is coated on the substrate 121, the protective sealant 123 may permeate and fill the grooves 124. Since the protective sealant 123 is also filled in the grooves 124, on one hand, the contact area between the protective sealant 123 and the substrate 121 is increased, thereby improving the adhesion effect between the two. On the other hand, the volume of the protective sealant 123 is further increased, which is beneficial to reducing the amount of deformation. However, the design of the grooves 124 of the substrate 121 may increase the amount of deformation of the substrate 121. Therefore, it is more conducive to achieving a balance between the degree of deformation of the protective sealant 123 and that of the substrate 121.

The above-mentioned design of the grooves 124 may also expand the heat dissipation area on the front side of the substrate 121, thus achieving a satisfactory heat dissipation effect. As another implementation, the grooves 124 are also filled with a heat dissipation material, such as transparent graphene particles, and then the grooves 124 are covered with the protective sealant 123 to further improve the heat dissipation capability through the heat dissipation material.

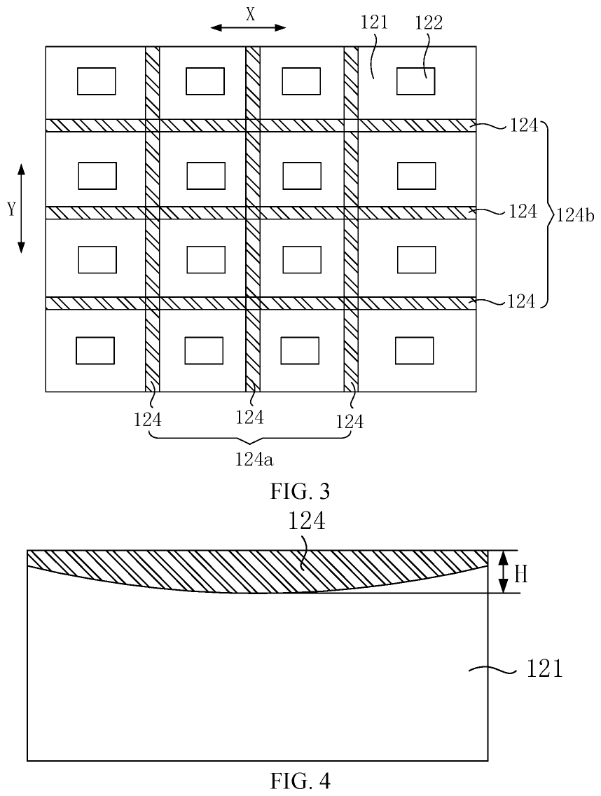

As shown in FIG. 3, as a specific implementation of the groove 124, the groove 124 adopts an elongated strip design, and the grooves 124 in the substrate 121 are arranged in a grid shape. Specifically, all the grooves 124 in the substrate 121 are divided into a first groove group 124a and a second groove group 124b. The plurality of grooves 124 in the first groove group 124a are arranged along a first orientation X. The plurality of grooves 124 in the second groove group 124b are arranged along a second orientation Y. The first orientation X and the second orientation Y are respectively parallel to two vertical sides of the substrate 121. In the first groove group 124a, both ends of the groove 124 extend in the second orientation Y, and the two ends of the groove 124 are flush with two opposite sides of the substrate 121, respectively. In the second groove group 124b, both ends of the groove 124 extend in the first orientation X, and the two ends of the groove 124 are flush with the other two opposite sides of the substrate 121, respectively.

In this scheme, since the groove 124 is elongated and extends to both sides of the substrate 121, the deformation amount of the substrate 121 at the groove 124 will be further increased. Furthermore, the surface of the substrate 121 at the groove 124 is more likely to have a slightly convex shape like the protective sealant 123, so that the deformation degree of the substrate 121 is similar to the deformation degree of the protective sealant 123, further reducing the relative displacement between the protective sealant 123 and the substrate 121 at the position of the light-emitting element 122.

Of course, the grooves 124 on the substrate 121 may also be strip structures all arranged along the first orientation X, or strip structures all arranged along the second orientation Y, or dot-like structures arranged in an array on the substrate 121.

On the basis that the groove 124 is elongated, as a further implementation of the groove 124, the depth of the groove 124 may change as a gradient. As shown in FIG. 4, in the first groove group 124a, the depth H of each of the grooves 124 gradually decreases from the middle to both ends. In the second groove group 124b, the depth H of each of the grooves 124 gradually decreases from the middle to both ends.

In this implementation, since the depth H of the groove 124 gradually decreases from the middle to both ends, and the grooves 124 in the substrate 121 are arranged in a grid, the depth of the groove 124 at the central portion of the substrate 121 is greater than the depth of the groove 124 at the peripheral portions of the substrate 121. As a result, when the substrate 121 expands due to heat, the deformation amount of the middle portion of the substrate 121 is greater than the deformation amount of the edge portions of the substrate 121, so that the deformation of the middle area of the substrate 121 is similar to that of the central area of the protective sealant 123, which is beneficial to reducing the relative displacement between the protective sealant 123 and the substrate 121 at the position of the light-emitting element 122.

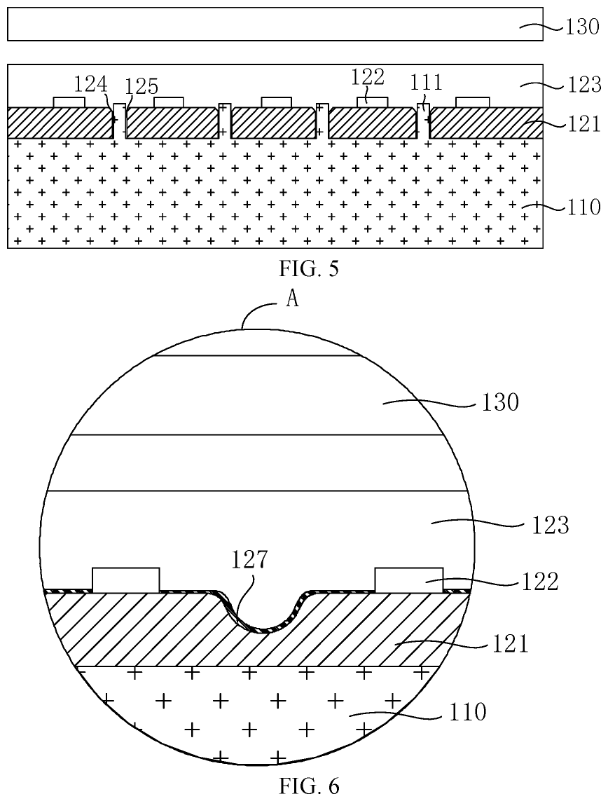

As shown in FIG. 5, as an another further implementation of groove 124, on the basis that the groove 124 is elongated and the depth of the groove 124 remains unchanged or gradually changes, the grooves 124 in the first groove group 124a meet with the grooves 124 in the second groove group 124b to form an intersection. The grooves 124 in the substrate 121 are arranged in a grid shape, and the intersections of the grooves 124 are arranged in an array of points on the substrate 121.

Furthermore, the substrate 121 defines a through hole 125 corresponding to the intersection. A plurality of positioning posts 111 may be disposed on the side of the backplate 110 facing the light plate assembly 120. The through hole 125 and the positioning post 111 may be provided at every intersection, or may be provided only at some intersections. Alternatively, the number of positioning posts 111 may also be designed to be less than the number of through holes 125, so that the positioning posts 111 are present only at some of the through holes 125.

During the process of assembling the light emitting module 100, the through holes 125 in the substrate 121 of the light plate assembly 120 may be aligned with the positioning posts 111 on the backplate 110 to facilitate the installation of the light plate assembly 120 in the corresponding area, and there will be no offset problem during the fixation of the light plate assembly 120. Furthermore, the positioning posts 111 may be designed into an asymmetric pattern to enhance the fool-proof design of the installation of the light plate assembly 120 and avoid installation errors of the light plate assembly 120, thus speeding up the installation efficiency of the light-emitting module 100.

In this implementation, the positioning posts 111 and the backplate 110 are integrally formed, and both are made of metal materials, which has satisfactory heat dissipation effect. After the light plate assembly 120 is installed on the backplate 110, the positioning posts 111 are inserted from the through holes 125 so as to contact the protective sealant 123 in the grooves 124, so that the backplate 110 and the positioning posts 111 can directly dissipate heat from the protective sealant 123, thereby improving the heat dissipation effect of the protective sealant 123. This is beneficial to reducing the deformation amount of the protective sealant 123 when heated, and preventing excessive displacement of the protective sealant 123 from squeezing the light-emitting element 122 when heated.

Furthermore, after the light plate assembly 120 is installed, the height of the positioning post 111 may be made to protrude higher than the surface height of the substrate 121. Or, it may be expressed as that the height of the end of the positioning post 111 facing away from the backplate 110 is higher than the height of the side of the substrate 121 facing away from the backplate 110.

Through the above further solution, the portion of the positioning post 111 inside the groove 124 is in contact with the portion of the protective sealant 123 filled in the groove 124, and the portion of the positioning post 111 above the groove 124 is in contact with the main part of the protective sealant 123, so that the positioning post 111 has a larger contact area with the protective sealant 123, which is beneficial to further improving the heat dissipation effect for the protective sealant 123. Furthermore, since the content of the protective sealant 123 filled in the groove 124 is relatively small, the protective sealant 123 inside the groove 124 is greatly affected by the heat on the substrate 121 and can easily conduct heat from the substrate 121. Therefore, contacting the positioning post 111 with the main body of the protective sealant 123 above the groove 124 may improve the heat dissipation efficiency of the protective sealant 123 directly by the positioning post 111.

Furthermore, the surface of the positioning post 111 may be coated with a reflective coating, or other reflective designs may be added to the positioning post 111, or the surface of the positioning post 111 may be polished to make the surface of the positioning post 111 smooth and mirror reflective.

Since the positioning post 111 forms a reflective structure, the positioning post 111 not only has a heat dissipation effect, but also may reflect light to the optical film 130 or other areas, improving the utilization rate of light and avoiding the problem of dark shadows at the intersection of the grooves 124.

As another implementation, as shown in FIG. 6, on the basis that the groove 124 is strip-shaped or dot-shaped, the inner wall of the groove 124 is made into an arc shape, and a reflective layer 127 is disposed inside the groove 124. The groove 124 and the reflective layer 127 together form a concave mirror structure.

The reflective layer 127 may be disposed only on the inner wall of the groove 124, or may be disposed on both the inner wall of the groove 124 and the entire upper surface of the substrate 121. The reflective layer 127 may be sprayed onto the inner wall of the groove 124 using paint, or may be attached to the inner wall of the groove 124 using a thin film structure.

In this embodiment, a concave mirror structure is formed at the groove 124, which has a light-gathering effect and may gather the light irradiated by the light-emitting elements 122 into the groove 124 and reflect it out from all angles to avoid the problem of relatively lower brightness in the area between adjacent light-emitting elements 122, thereby improving the overall light output uniformity of the light plate assembly 120.

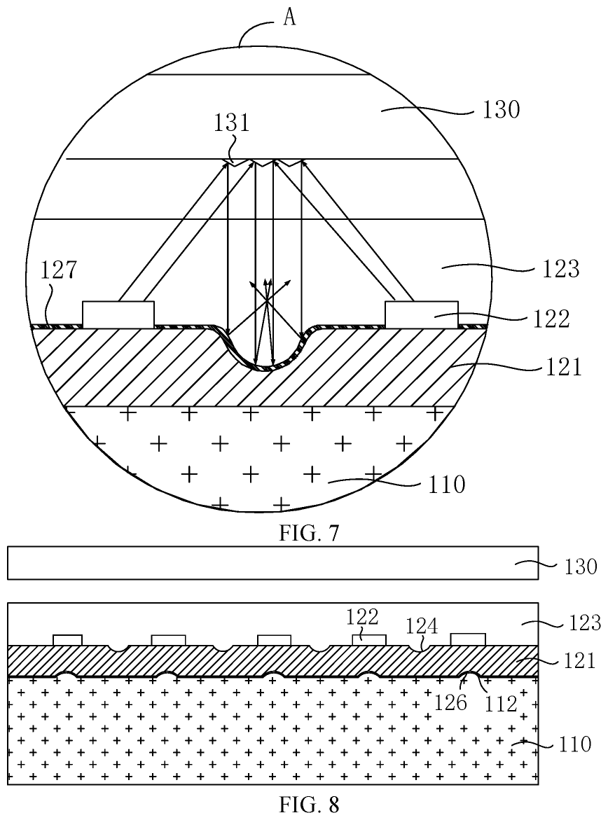

Further, as shown in FIG. 7, a prism 131 is disposed on the side of the optical film 130 facing the substrate 121. The prism 131 may be pasted on the bottom of the optical film 130 through an optical glue, or the optical film 130 may also be partially designed into the shape of the prism 131 by adjusting the structure of the optical film 130.

The area where the prism 131 is located lies between adjacent light-emitting elements 122, and the orthographic projection of the prism 131 on the backplate 110 only covers the orthographic projection of the groove 124 on the backplate 110. Therefore, the prism 131 may hardly affect the overall effect of the illumination of the light emitting unit 122 onto the optical film 130. In the area above the groove 124, part of the light is reflected on the surface of the prism 131, and the light is reflected to the position of the groove 124, so that the light is gathered through the groove 124 to increase the brightness of the gap area between adjacent light-emitting elements 122.

In addition, as shown in FIG. 8, in some embodiments according to this application, a plurality of channels 126 may also be defined in the back side of the substrate 121, that is, the side of the substrate 121 facing the backplate 110. The orthographic projection of the channel 126 in the backplate 110 may overlap the orthographic projection of the respective light emitting unit(s) 122 on the backplate 110. The grooves 124 and channels 126 may both be strip-shaped or may both be dot-shaped. Since the grooves 124 and the channels 126 are designed to be misaligned relative to each other, the structural strength of the substrate 121 will not be affected. Secondly, designing the channel 126 in the back of the substrate 121 may make the heat dissipation area on the back of the substrate 121 larger, which is more conducive to the heat dissipation of the light plate assembly 120. In addition, since the channel 126 is located directly below the light-emitting element 122, the channel 126 is very close to the light-emitting element 122, so that the light-emitting element 122 obtains a larger heat dissipation area, further improving the heat dissipation effect of the light-emitting element 122.

Furthermore, the backplate 110 includes a plurality of bosses 112 on the side facing the substrate 121, and the bosses 112 are fitted with the channels 126 in a one-to-one correspondence. After the light plate assembly 120 is installed, the bosses 112 are embedded into the channels 126. That is, the bosses 112 are added to the backplate 110 to facilitate the alignment and installation of the light plate assembly 120. Secondly, the contact area between the backplate 110 and the light plate assembly 120 may be increased to improve the heat dissipation effect. Third, the movement of the substrate 121 when it expands due to heat is restricted from the back side of the substrate 121 to improve the fixation between the substrate 121 and the backplate 110.

The foregoing is merely a further detailed description of this application made with reference to some specific illustrative embodiments, and the specific implementations of this application are not to be construed to be limited to these illustrative embodiments. For those having ordinary skill in the technical field to which this application pertains, numerous deductions or substitutions may be made without departing from the concept of this application, which shall all be regarded as falling in the scope of protection of this application.

What is claimed is:

1. A light-emitting module, comprising a substrate, a plurality of light-emitting elements disposed in an array on the substrate, and a protective sealant covering the plurality of light-emitting elements; wherein the protective sealant has a thermal expansion rate that is greater than a thermal expansion rate of the substrate; wherein there is defined a plurality of grooves in a side of the substrate facing the protective sealant, and wherein each groove is disposed between adjacent light-emitting elements.

2. The light-emitting module as recited in claim 1, wherein the plurality of grooves are divided into a first groove group and a second groove group, wherein a plurality of grooves of the first groove group are disposed along a first orientation, and a plurality of grooves of the second groove group are disposed along a second orientation; wherein the first orientation and the second orientation are respectively parallel to two vertical sides of the substrate;
wherein of the first groove group, both ends of each groove extend in the second orientation, and wherein the two ends of the groove are respectively flush with two opposite sides of the substrate;
wherein of the second groove group, both ends of each groove extend in the first orientation, and wherein the two ends of the groove are respectively flush with another two opposite sides of the substrate.

3. The light-emitting module as recited in claim 2, wherein in the first groove group, a depth of each groove gradually decreases in a direction from a middle to both ends thereof; wherein in the second groove group, a depth of each groove gradually decreases from a middle to both ends thereof.

4. The light-emitting module as recited in claim 2, further comprising a backplate on which the substrate is disposed; wherein the plurality of grooves in the first groove group meet with the plurality of grooves in the second groove group to form an intersection, and wherein there is defined a through hole corresponding to the intersection.

5. The light-emitting module as recited in claim 4, wherein the backplate comprises a plurality of positioning posts disposed on a side of the backplate facing the substrate; wherein the plurality of positioning posts are integrally formed with the backplate, wherein the plurality of positioning posts are disposed in one-to-one correspondence with the respective through holes; wherein each of the plurality of positioning posts penetrates the respective through hole to be in contact with the protective sealant.

6. The light-emitting module as recited in claim 5, wherein a height of an end of each positioning post facing away from the backplate is higher than a height of the side of the substrate away from the backplate.

7. The light-emitting module as recited in claim 6, wherein a surface of each positioning post is coated with a reflective coating.

8. The light-emitting module as recited in claim 1, wherein the plurality of grooves are each of an elongated shape and wherein all the plurality of grooves are disposed along a first orientation.

9. The light-emitting module as recited in claim 1, wherein the plurality of grooves are each of elongated shape and wherein all the plurality of grooves are disposed along a second orientation.

10. The light-emitting module as recited in claim 1, wherein the plurality of grooves are disposed in a dot-like pattern on the substrate.

11. The light-emitting module as recited in claim 1, further comprising a backplate on which the substrate is disposed; wherein a plurality of channels are defined in a side of the substrate facing the backplate, wherein an orthographic projection of each of the plurality of channels on the backplate overlaps an orthographic projection of the respective light-emitting elements on the backplate.

12. The light-emitting module as recited in claim 11, wherein a plurality of bosses are disposed on a side of the backplate facing the substrate, and wherein the plurality of bosses are fitted with the plurality of grooves in one-to-one correspondence.

13. The light-emitting module as recited in claim 1, wherein an inner wall of each of the plurality of grooves is arc-shaped, and a reflective layer is disposed in the groove, and wherein the groove and the reflective layer jointly form a concave mirror structure.

14. The light-emitting module as recited in claim 13, wherein the reflective layer is disposed on both the inner wall of each groove and a side of the substrate facing the protective sealant.

15. The light-emitting module as recited in claim 13, wherein the reflective layer is only disposed on the inner wall of each groove.

16. The light-emitting module as recited in claim 13, further comprising a backplate and an optical film, wherein the substrate is disposed on the backplate, wherein the optical film is disposed on the side of the protective sealant away from the substrate, wherein the optical film comprises a prism disposed on a side facing the substrate, and wherein an orthographic projection of the prism on the backplate covers an orthographic projection of the respective groove on the backplate.

17. The light-emitting module as recited in claim 1, wherein the protective sealant is also filled in each groove.

18. The light-emitting module as recited in claim 1, wherein each groove is filled with a heat dissipation material.

19. A light-emitting module, comprising a substrate, a plurality of light-emitting elements disposed in an array on the substrate, and a protective sealant covering the plurality of light-emitting elements; wherein the protective sealant has a thermal expansion rate that is greater than a thermal expansion of the substrate;
wherein there is defined a plurality of grooves in a side of the substrate facing the protective sealant, and wherein each groove is arranged between adjacent light-emitting elements;
wherein the plurality of grooves are divided into a first groove group and a second groove group, wherein a plurality of grooves in the first groove group are disposed alone a first orientation, and wherein a plurality of grooves in the second groove group are disposed along a second orientation; wherein the first orientation and the second orientation are respectively parallel to two vertical sides of the substrate;
wherein of the first groove group, both ends of each groove extend in the second orientation, and wherein the two ends of the groove are respectively flush with two opposite sides of the substrate;
wherein of the second groove group, both ends of the groove extend in the first orientation, and wherein the two ends of the groove are respectively flush with another two opposite sides of the substrate;
wherein in the first groove group, a depth of each groove gradually decreases in a direction from a middle to both ends thereof, wherein in the second groove group, a depth of each groove gradually decreases from a middle to both ends thereof;
wherein the light-emitting module further comprises a backplate on which the substrate is disposed, wherein the plurality of grooves in the first groove group meet with the plurality of grooves in the second groove group to form an intersection, and wherein there is defined a through hole corresponding to the intersection;
wherein the backplate comprises a plurality of positioning posts disposed on the side of the backplate facing the substrate; wherein the plurality of positioning posts are integrally formed with the backplate, and wherein the plurality of positioning posts are disposed in one-to-one correspondence with the respective through holes; wherein each of the plurality of positioning posts penetrates the respective through hole to be in contact with the protective sealant.

20. A display device, comprising a driving circuit and a light-emitting module, the driving circuit being used to drive the light-emitting module; wherein the light-emitting module comprises a substrate, a plurality of light-emitting elements disposed in an array on the substrate, and a protective sealant covering the plurality of light-emitting elements; wherein the protective sealant has a thermal expansion rate that is greater than a thermal expansion rate of the substrate; wherein there is defined a plurality of grooves in a side of the substrate facing the protective sealant, and wherein each groove is arranged between adjacent light-emitting elements.
